(19) United States
(12) Patent Application Publication
(10) Pub. No.: US 2018/0224588 A1
(43) Pub. Date: Aug. 9, 2018

(54) POLARIZING PLATE AND MANUFACTURING METHOD THEREOF, DISPLAY PANEL AND MANUFACTURING METHOD THEREOF, AND DISPLAY DEVICE AND MANUFACTURING METHOD THEREOF

(71) Applicants: BOE Technology Group Co., Ltd., Beijing (CN); Beijing BOE Optoelectronics Technology Co., Ltd., Beijing (CN)

(72) Inventors: Cheng Chang, Beijing (CN); Jiaqiang Wang, Beijing (CN); Dawei Wang, Beijing (CN)

(21) Appl. No.: 15/570,985

(22) PCT Filed: May 3, 2017
(86) PCT No.: PCT/CN2017/082908

§ 371 Date: Oct. 31, 2017

(30) Foreign Application Priority Data
Jun. 29, 2016 (CN) 201610488301.2

(51) Int. Cl. G02B 5/30; G02F 1/1368; G02F 1/1335; H01L 27/02

(52) U.S. Cl. CPC G02B 5/3058; G02F 1/1368; G02F 1/133514; H01L 27/1214; H01L 27/0292; G02F 2202/22; G02F 1/133528

(57) ABSTRACT

The present disclosure relates to a polarizing plate and a manufacturing method thereof, a display panel and a manufacturing method thereof, and a display device and a manufacturing method thereof. The polarizing plate includes a polarizing layer and a conductive layer on the polarizing laver. The conductive layer includes a first area having a first thickness and a second area having a second thickness, the first thickness is greater than the second thickness and the first area includes at least a portion of an edge area of the conductive laver.

### CROSS REFERENCE OF RELATED APPLICATION

The present application claims priority to Chinese Patent Application No. 201610488301.2, filed on Jun. 29, 2016, which is incorporated herein by reference in its entirety as a part of the present application.

### TECHNICAL FIELD

The present disclosure relates to the technical field of displays, and more particularly, to a polarizing plate and a manufacturing method thereof, a display panel and a manufacturing method thereof, and a display device and a manufacturing method thereof.

### BACKGROUND

At present, with the quick development of the liquid crystal industry for cell phones, touch and display driver integration (TDDI) technologies have been applied by more and more module factories, have been widely promoted and thus have become a future trend.

For conventional TDDI technique, during the process of manufacturing modules, a sliver paste needs to be coated at a fixed position of the panel to connect the upper glass substrate to the lower glass substrate, and the sliver paste contacts with the upper polarizing plate. The sliver paste is used to connect a thin film transistor (TFT) substrate to a polarizing plate back adhesive, so that the static electricity on the TFT substrate is transferred to the polarizing plate back adhesive. However, on the one hand, as the manufacturing cost of the silver paste is high, the manufacturing cost for the above solution is also high. On the other hand, the polarizing plate contracts due to influence of temperature, causing the polarizing plate to separate from the silver paste. As a result, the silver paste cannot connect the TFT substrate to the polarizing plate back adhesive, causing the static electricity to remain on the TFT substrate without being able to be released, and therefore causing poor display.

### SUMMARY

The embodiments of the present disclosure provide a polarizing plate and a manufacturing method thereof, a display panel and a manufacturing method thereof, and a display device and a manufacturing method thereof, which can solve the technical problems of high manufacturing cost and poor display due to failed release of static residue on the TFT substrate in the prior art.

The present disclosure is to provide a polarizing plate.

In a first aspect of the present disclosure, a polarizing plate is provided. The polarizing plate comprises a polarizing layer and a conductive layer on the polarizing layer. The conductive layer comprises a first area having a first thickness and a second area having a second thickness. The first thickness is greater than the second thickness and the first area comprises at least a portion of an edge area of the conductive layer.

In one embodiment, the conductive layer comprises a first conductive layer and a second conductive layer on the first conductive layer. Wherein, the first conductive layer is located in the first and second areas, and the second conductive layer is located in the first area.

In one embodiment, the hardness of the second conductive layer is smaller than that of the first conductive layer.

In one embodiment, a difference between the first thickness and the second thickness is about 0.15 mm to about 0.20 mm.

In one embodiment, the conductive layer includes an adhesive having conductive particles.

In one embodiment, the adhesive includes a polymer material.

In one embodiment, at least a portion of an edge of the first area of the polarizing plate has a recess.

The present disclosure is further to provide a display panel.

In a second aspect of the present disclosure, a display panel is provided. The display panel comprises: a first substrate, and a second substrate on the first substrate. The second substrate exposes at least a portion of the first substrate. The display panel further comprises the polarizing plate described above. The polarizing plate is arranged on the first substrate and the second substrate, the second area of the polarizing plate is in contact with the second substrate, and the first area of the polarizing plate is in contact with an exposed portion of the first substrate.

In one embodiment, the first substrate includes a thin film transistor substrate and the second substrate includes a color filter substrate.

The present disclosure is further to provide a display device.

In a third aspect of the present disclosure, a display device is provided. The display device comprises the display panel described above.

The present disclosure is further to provide a method of manufacturing a polarizing plate.

In a fourth aspect of the present disclosure, a method of manufacturing a polarizing plate is provided. The method comprises: forming a polarizing layer; and forming a conductive layer on the polarizing layer, wherein the conductive layer is configured to include a first area having a first thickness and a second area having a second thickness, the first thickness is greater than the second thickness and the first area includes at least a portion of an edge area of the conductive layer.

In one embodiment, forming the conductive layer comprises: forming a first conductive layer on the polarizing layer; forming a second conductive layer on the first conductive layer, and ensuring the first conductive layer is located in the first area and the second area, and the second conductive layer is located in the first area.

In one embodiment, the hardness of the second conductive layer is smaller than that of the first conductive layer.

In one embodiment, a difference between the first thickness and the second thickness is about 0.15 mm to about 0.20 mm.

In one embodiment, the conductive layer includes an adhesive having conductive particles.

In one embodiment, the adhesive includes a polymer material.

In one embodiment, the method further comprises: removing at least a portion of an edge of the first area of the polarizing plate to form a recess.

The present disclosure is further to provide a method of manufacturing a display panel.

In a fifth aspect of the present disclosure, a method of manufacturing a display panel is provided. The method comprises: providing a first substrate and a second substrate on the first substrate. The second substrate exposes at least a portion of an edge of the first substrate. The method further comprises: the method of manufacturing a polarizing plate described above; and attaching the polarizing plate to the second substrate to cause the first area of the polarizing plate to contact with the first substrate and to cause the second area of the polarizing plate to contact with the second substrate.

In one embodiment, the first substrate comprises a thin film transistor substrate and the second substrate includes a color filter substrate.

The present disclosure is further to provide a method of manufacturing a display device.

In a sixth aspect of the present disclosure, a method of manufacturing a display device is provided. The method comprises the method of manufacturing a display panel described above.

### BRIEF DESCRIPTION OF THE DRAWINGS

To describe the technical solutions in the embodiments of the present disclosure more clearly, the following briefly introduces the accompanying drawings required for describing the embodiments. The accompanying drawings in the following description show some embodiments of the present disclosure, and are not intended to limit the present disclosure.

FIG. 1 is a sectional structural diagram of a polarizing plate in accordance with an embodiment of the present disclosure;

FIG. 2 is a sectional structural diagram of a polarizing plate in accordance with an embodiment of the present disclosure;

FIG. 3 is a top view of a polarizing plate in accordance with an embodiment of the present disclosure;

FIG. 4 is a sectional structural diagram of a display panel in accordance with an embodiment of the present disclosure;

FIG. 5 is a sectional structural diagram of a display panel in accordance with an embodiment of the present disclosure;

FIG. 6 is a flowchart of an embodiment of the present disclosure;

FIG. 7 is a flowchart of an embodiment of the present disclosure;

FIG. 8 is a flowchart of an embodiment of the present disclosure.

### DETAILED DESCRIPTION

To make the objects, technical solutions and advantages of the embodiments of the present disclosure clearer, the followings will clearly and completely describe the technical solutions of the embodiments of the present disclosure with reference to the drawings. The described embodiments show some rather than all embodiments of the present disclosure. Based on the described embodiments of the present disclosure, all other embodiments derived by those skilled in the art without any creative work fall into the protection scope of the present disclosure.

When introducing the elements and embodiments of the present disclosure, the articles “a/an”, “one”, “the” and “said” intend to indicate the presence of one or more elements. The wording of “comprise”, “include”, “have” or “consist of” intends to mean open inclusion and intends to indicate the presence of other elements in addition to the listed ones.

For the sake of literal description in the followings, as the marked directions in the drawings, the terms “upper”, “lower”, “left”, “right”, “perpendicular”, “horizontal”, “top”, “bottom” and derivatives thereof should be involved in the present disclosure. The terms of “cover”, “on top of”, “positioned above” or “positioned on top of” means that a first element of a first structure, for example, is located on/above a second element of a second structure. Here, there may be an intermediate element such as an interface structure between the first and second elements. The term of “contact” means connection between a first element of a first structure, for example, and a second element of a second structure. There may be or may not be other elements in the interface of the two elements.

Unless specifically indicated in the context, a singular form of the words used in the present text and the appended claims includes a plural form, and vice versa. Therefore, when a singular number is mentioned, usually the plural number of the corresponding term should be included. Similarly, the terms of “comprise” and “include” should be construed as openly including rather than exclusively including. Similarly, the terms of “include” and “or” should be construed as including, unless the present text clearly prohibits such explanations. Where the term of “example” is used in the present text, particularly when the term follows a group of terms, the term of “example” is only to indicate an exemplary and illustrative description, and shall not be considered as an exclusive or general description.

FIG. 1 is a sectional schematic diagram of a polarizing plate in accordance with an embodiment of the present disclosure. As shown in FIG. 1, in an embodiment of the present disclosure, the polarizing plate includes a polarizing layer 1 and a conductive layer 2 on the polarizing layer 1. The conductive layer 2 includes a first area R1 having a first thickness h1 and a second area R2 having a second thickness h2. Here, the first thickness h1 is greater than the second thickness h2 and the first area R1 includes at least a portion of an edge area of the conductive layer 2.

The conductive layer may include an adhesive including conductive particles. The adhesive may include a polymer material.

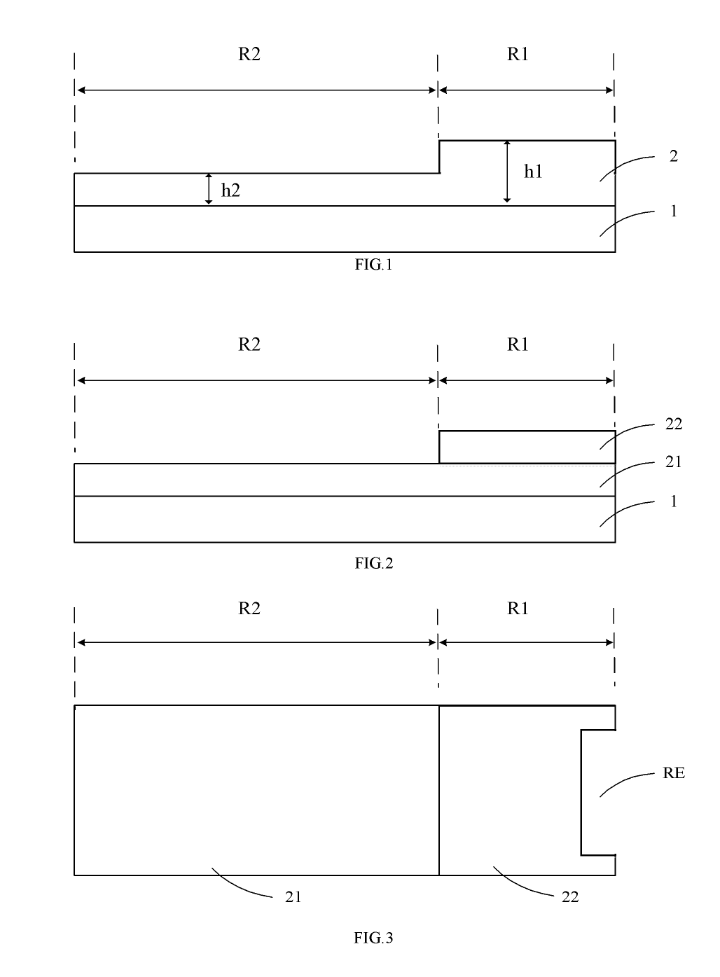

FIG. 2 is a sectional schematic diagram of a polarizing plate in accordance with an embodiment of the present disclosure. In the polarizing plate shown in FIG. 2, the conductive layer includes a first conductive layer and a second conductive layer on the first conductive layer. As shown in FIG. 2, the polarizing plate includes a polarizing layer 1, a first conductive layer 21 on the first polarizing layer land a second conductive layer 22 on the first conductive layer 21. It can be known from FIG. 2 that the first conductive layer 21 is located in the both the first area R1 and the second area R2, and the second conductive layer 22 is located in the first area R1. In other words, the second conductive layer covers at least a portion of an edge area of the first conductive layer.

In one embodiment, the second conductive layer is softer than the first conductive layer. That is, the hardness of the second conductive layer is smaller than that of the first conductive layer so as to better protect the first substrate and to reduce the hard contact between the conductive layer and the first substrate. The first conductive layer and the second conductive layer may include adhesives having conductive particles. The adhesives may include polymer materials.

In one embodiment, a difference between the first thickness and the second thickness is about 0.15 mm to about 0.20 mm. That is, in a case where the conductive layer includes the first conductive layer and the second conductive layer on the first conductive laver, a thickness range of the second conductive layer is about 0.15 mm to about 0.20 mm. In addition, the second thickness may be about 20 μm.

FIG. 3 is a top view of a polarizing plate in accordance with an embodiment of the present disclosure. In the embodiment shown in FIG. 3, at least a portion of an edge area of the first area R1 of the polarizing plate has a recess RE. It can be known from FIG. 3 that the second conductive layer 22 covers at least a portion of an edge area of the first conductive layer 21. For example, when the polarizing plate in the present embodiment is used in a display panel, a bonding IC may be arranged at the recess RE.

The embodiments of the present disclosure further provide a display panel. The display panel comprises a first substrate and a second substrate on the first substrate. The second substrate exposes at least a portion of the first substrate. The display panel further comprises a polarizing plate provided in the embodiments of the present disclosure. The polarizing plate is arranged on the first substrate and the second substrate, the second area of the polarizing plate is in contact with the second substrate, and the first area of the polarizing plate is in contact with an exposed portion of the first substrate.

FIG. 4 is a sectional schematic diagram of a display panel in accordance with an embodiment of the present disclosure. As shown in FIG. 4, the display panel includes a first substrate S1 and a second substrate S2 on the first substrate S1. The second substrate S2 exposes at least a portion of an edge of the first substrate S2. The display panel further includes the polarizing plate having the polarizing layer 1 and the conductive layer 2 provided in the embodiments of the present disclosure. The polarizing plate is arranged on the first substrate S1 and on the second substrate S2. In addition, the second area R2 of the polarizing plate is in contact with the second substrate S2, and the first area R1 of the polarizing plate is in contact with the exposed portion of the first substrate S1.

It should be noted that for the display panel shown in FIG. 4, there is a space between the second substrate and the first area in a direction parallel with an extending direction of the second substrate S2. However, the display panel may also be designed to be with no space between the second substrate and the first area in accordance with the actual needs.

FIG. 5 is a sectional schematic diagram of a display panel in accordance with an embodiment of the present disclosure. As shown in FIG. 5, the display panel comprises a first substrate S1 and a second substrate S2 on the first substrate S1. The second substrate S2 exposes at least a portion of an edge of the first substrate S2. The display panel further comprises the polarizing plate having the polarizing layer 1, the first conductive layer 21 and the second conductive layer 22 provided in the embodiments of the present disclosure. The polarizing plate is arranged on the first substrate S1 and on the second substrates S2. In addition, the second area R2 of the polarizing plate contacts with the second substrate S2, and the first area R1 of the polarizing plate contacts with the exposed portion of the first substrate S1.

It should be noted that for the display panel shown in FIG. 5, there is a space between the second substrate and the first area in a direction parallel with an extending direction of the second substrate S2. However, the display panel may also be designed to be with no space between the second substrate and the first area in accordance with the actual needs.

In one embodiment, the first substrate includes a thin film transistor (TFT) substrate, and the second substrate includes a color filter (CF) substrate.

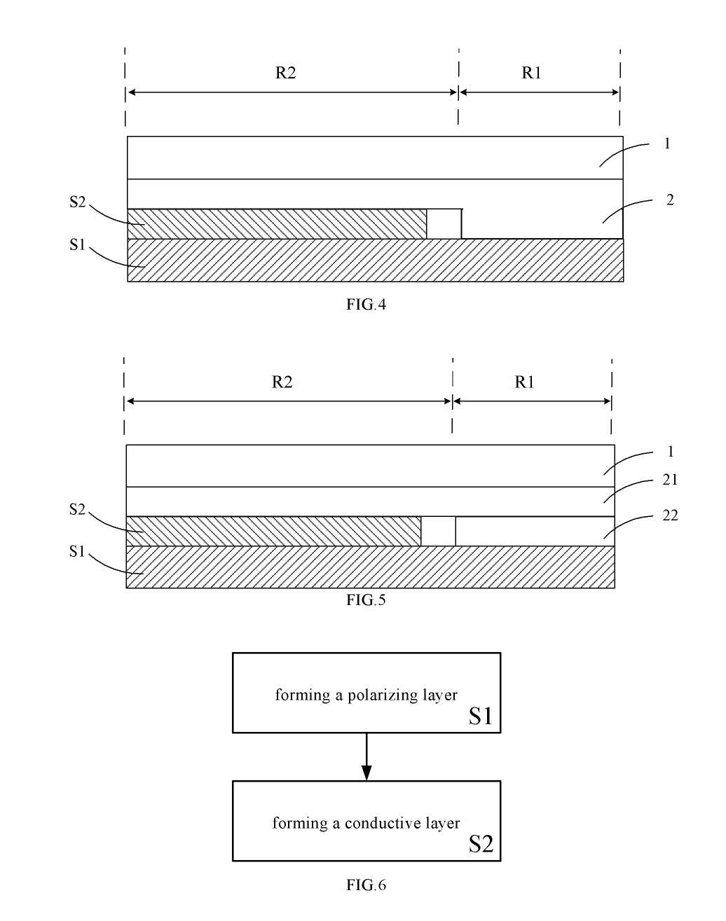

FIG. 6 is a flowchart in accordance with an embodiment of the present disclosure. It can be known from FIG. 6 that the method of manufacturing a polarizing plate provided in the embodiments of the present disclosure includes the following steps:

S1. forming a polarizing layer; and

S2. forming a conductive layer on the polarizing layer, wherein the conductive layer is configured to include a first area having a first thickness and a second area having a second thickness, the first thickness is greater than the second thickness and the first area includes at least a portion of an edge area of the conductive layer.

In one embodiment, the conductive layer may be formed by using an adhesive having conductive particles. The adhesive may include a polymer material.

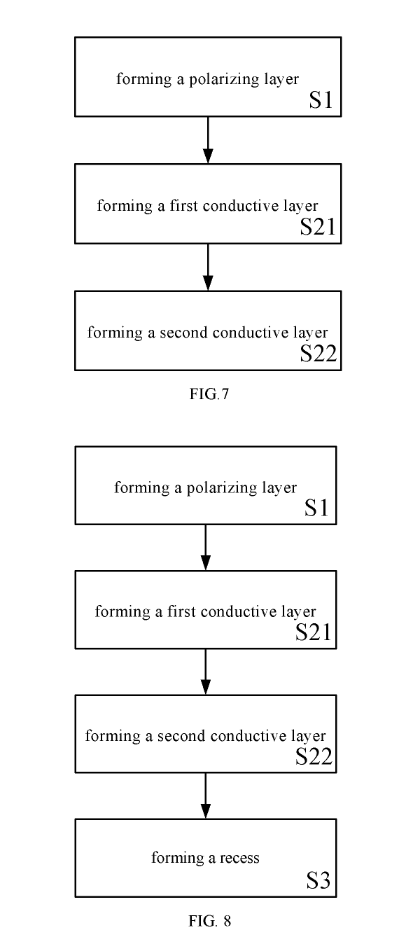

FIG. 7 is a flowchart in accordance with an embodiment of the present disclosure. In an embodiment, the steps of forming the conductive layer include step S21 of forming a first conductive layer and a step S22 of forming a second conductive layer. Here, as shown in FIG. 7, the method of manufacturing a polarizing plate provided in the present embodiment includes the following steps:

S1: forming a polarizing layer;

S21. forming a first conductive layer on the polarizing layer; and

S22. forming a second conductive layer on the first conductive layer and ensuring the first conductive layer is located in the first area and the second area, and the second conductive layer is located in the first area.

In an embodiment, the hardness of the second conductive layer is smaller than that of the first conductive layer so as to better protect the first substrate and to reduce the hard contact between the conductive layer and the first substrate.

A difference between the first thickness and the second thickness may be about 0.15 mm to about 0.20 mm. That is, in a case where the conductive layer includes the first conductive layer and the second conductive layer on the first conductive layer, a thickness range of the second conductive layer is about 0.15 mm to about 0.20 mm. In addition, the second thickness may be about 20 μm.

FIG. 8 is a flowchart in accordance with an embodiment of the present disclosure. In one embodiment, the method of manufacturing a polarizing plate further comprises: removing at least a portion of an edge of the first area of the polarizing plate to form a recess. As shown in FIG. 8, the method of manufacturing a polarizing plate in the present embodiment includes the following steps:

S1: forming a polarizing layer;

S21. forming a first conductive layer on the polarizing layer;

S22. forming a second conductive layer on the first conductive layer, and ensuring the first conductive layer is located in the first area and the second area, and the second conductive layer is located in the first area; and

S3. removing at least a portion of an edge of the first area of the polarizing plate to form a recess.

The embodiments of the present disclosure further provide a method of manufacturing of display panel. The method comprises: providing a first substrate and a second substrate on the first substrate, wherein the second substrate exposes at least a portion of an edge of the first substrate. The method of manufacturing of display panel further comprises: the method of manufacturing a polarizing plate described above; and

attaching the polarizing plate to the second substrate to cause the first area of the polarizing plate to contact with the first substrate and to cause the second area of the polarizing plate to contact with the second substrate.

In an embodiment, the first substrate includes a thin film transistor (TFT) substrate, and the second substrate includes a color filter (CF) substrate.

The embodiments of the present disclosure further provide a display device and a manufacturing method thereof. The display device comprises the display panel described above, and the method of manufacturing the display device comprises the method of manufacturing the display panel described above. The display device may be a display panel, a display, a TV, a tablet computer, a cell phone, a navigator or any other device having a display function, which will not be limited in the present disclosure.

When the polarizing plate in the embodiments of the present disclosure is tested under the environment, the first area of the polarizing plate is always connected to the first substrate, although the polarizing plate contracts in a certain degree due to the influence of temperature.

The display panel (e.g., a liquid crystal display panel) provided in the embodiments of the present disclosure may ensure a static electricity conducting path on the first substrate (e.g., a thin film crystal substrate), thereby guaranteeing that there is no static residue on the first substrate (e.g., a thin film crystal substrate) and improving the, poor display.

In addition, as the first area of the polarizing plate is attached to the first substrate such as a TFT substrate, and as the conductive layer of the polarizing plate is soft, the polarizing plate provided in the embodiments of the present disclosure can effectively provide a buffering function during the testing procedure of the display panel or the display device, thereby reducing the risk of damaging the display panel or the display device (e.g., damage of the liquid crystal) during the testing.

Further, a silver paste may not be coated between the panel and the polarizing layer in accordance with the solutions of the embodiments of the present disclosure, thereby reducing the manufacturing cost of the product, saving the manufacturing process at the factory end and improving the utilization rate of the product.

Certain embodiments have been described in the present disclosure. These embodiments are only shown by way of examples, and are not intended to limit the scope of the present disclosure. In fact, the novel embodiments described in the present disclosure may be implemented in many other forms. In addition, various omissions, substitutions and modifications of the forms of the embodiments described in the present disclosure may be made without departing from the spirit of the present disclosure. The appended claims and their equivalents are intended to cover all such forms or modifications that fall within the scope and spirit of the present disclosure.

1. A polarizing plate, comprising a polarizing layer and a conductive layer on the polarizing layer, wherein
the conductive layer comprises a first area having a first thickness and a second area having a second thickness, the first thickness is greater than the second thickness and the first area includes at least a portion of an edge area of the conductive layer.

2. The polarizing plate according to claim 1, wherein the conductive layer comprises a first conductive layer and a second conductive layer on the first conductive layer, the first conductive layer is located in the first and second areas and the second conductive layer is located in the first area.

3. The polarizing plate according to claim 2, wherein the hardness of the second conductive layer is smaller than that of the first conductive layer.

4. The polarizing plate according to claim 1, wherein a difference between the first thickness and the second thickness is about 0.15 mm to about 0.20 mm.

5. The polarizing plate according to claim 1, wherein the conductive layer comprises an adhesive with conductive particles.

6. The polarizing plate according to claim 5, wherein the adhesive comprises a polymer material.

7. The polarizing plate according to claim 1, wherein at least a portion of an edge of the first area of the polarizing plate includes a recess.

8. A display panel, comprising a first substrate and a second substrate on the first substrate, wherein the second substrate exposes at least a portion of the first substrate, the display panel further comprises a polarizing plate, the polarizing plate comprises a polarizing layer and a conductive layer on the polarizing layer, the conductive layer comprises a first area having a first thickness and a second area having a second thickness, the first thickness is greater than the second thickness and the first area includes at least a portion of an edge area of the conductive layer, the polarizing plate is arranged on the first substrate and the second substrate, the second area of the polarizing plate is in contact with the second substrate, and the first area of the polarizing plate is in contact with an exposed portion of the first substrate.

9. The display panel according to claim 8, wherein the first substrate comprises a thin film transistor substrate and the second substrate comprises a color filter substrate.

10. A display device, comprising the display panel of claim 8.

11. A method of manufacturing a polarizing plate, comprising:
forming a polarizing layer; and
forming a conductive layer on the polarizing layer, wherein the conductive layer is configured to include a first area having a first thickness and a second area having a second thickness, the first thickness is greater than the second thickness and the first area includes at least a portion of an edge area of the conductive layer.

12. The method of manufacturing a polarizing plate according to claim 11, wherein forming the conductive layer comprises:
forming a first conductive layer on the polarizing layer;
forming a second conductive layer on the first conductive layer, and ensuring the first conductive layer is located in the first area and the second area, and the second conductive layer is located in the first area.

13. The method of manufacturing a polarizing plate according to claim 12, wherein the hardness of the second conductive layer is smaller than that of the first conductive layer.

14. The method of manufacturing a polarizing plate according to claim 11, wherein a difference between the first thickness and the second thickness is about 0.15 mm to about 0.20 mm.

15. The method of manufacturing a polarizing plate according to claim 14, wherein the conductive layer comprises an adhesive with conductive particles.

16. The method of manufacturing a polarizing plate according to claim 15, wherein the adhesive comprises a polymer material.

17. The method of manufacturing a polarizing plate according to claim 11, further comprising: removing at least a portion of an edge of the first area of the polarizing plate to form a recess.

18. A method of manufacturing a display panel, comprising providing a first substrate and a second substrate on the first substrate, wherein the second substrate exposes at least a portion of an edge of the first substrate; the method further comprising: the method of manufacturing a polarizing plate according claim 11; and
attaching the polarizing plate to the second substrate, to cause the first area of the polarizing plate in contact with the first substrate and to cause the second area of the polarizing plate in contact with the second substrate.

19. The manufacturing method according to claim 18, wherein the first substrate comprises a thin film transistor substrate and the second substrate comprises a color filter substrate.

20. A method of manufacturing a display device, comprising a method of manufacturing a display panel according to claim 18.
